(19) United States
(12) Patent Application Publication
(10) Pub. No.: US 2015/0357217 A1
(43) Pub. Date: Dec. 10, 2015

(54) WARPED SILICON-CHIP ADSORPTION DEVICE AND ADSORPTION METHOD THEREOF

(71) Applicant: SHANGHAI MICRO ELECTRONICS EQUIPMENTCO., LTD., Shanghai (CN)

(72) Inventors: Xinxin WANG, Shanghai (CN); Xuchu JIANG, Shanghai (CN); Tao XU, Shanghai (CN); Wenjing ZHU, Shanghai (CN); Fangxiong SUN, Shanghai (CN); Jun SUN, Shanghai (CN)

(73) Assignee: SHANGHAI MICRO ELECTRONICS EQUIPMENT CO,, LTD, Shanghai (CN)

(21) Appl. No.: 14/655,465

(22) PCT Filed: Dec. 26, 2013
(86) PCT No.: PCT/CN2013/090565

§ 371 Date: Jun. 25, 2015

(30) Foreign Application Priority Data
Dec. 28, 2012 (CN) 201210586817.2

(51) Int. Cl. H01L 21/67; H01L 21/683; G03F 7/20

(52) U.S. Cl. CPC H01L 21/67288; G03F 7/707; H01L 21/6838

(57) ABSTRACT

An apparatus and method for adsorbing a wafer are disclosed. The apparatus includes a chuck (100) for vacuum adsorption of the wafer and at least three suction head assemblies (200). The chuck (100) has at least three openings (101) corresponding to the suction head assemblies (200). The suction head assembly (200) includes: a pneumatic cylinder (230) in fixed connection with the chuck (100); and a nozzle (230) in movable connection to the pneumatic cylinder (210). The nozzles (230) are completely located within the respective openings (101) or at least partially above a surface of the chuck (100). Through increasing at least three suction head assemblies (200) in the chuck (100), the wafer (300) can be adsorbed and stretched by the suction head assembly (200) until the lower surface of the wafer (300) is attached to the upper surface of the chuck 100, thereby achieving the adsorption of the wafer (300).

### TECHNICAL FIELD

The present invention relates to the field of photolithography tools, and in particular, to an apparatus and a method for adsorbing a warped wafer.

### BACKGROUND

Photolithography tools are primarily used in the fabrication of integrated circuits (ICs) or other micro devices. With a photolithography tool, distinct patterns formed in multiple accurately aligned masks are successively imaged by exposure on a photoresist-coated wafer such as, for example, a semiconductor wafer or a wafer for forming a light emitting diode (LED) display.

Existing photolithography tools include step-and-repeat ones and step-and-scan ones, each of which needs to incorporate suitable devices for respectively carrying the mask and wafer to make accurate relative movements, in order to meet the requirements of photolithography. In these devices, the component carrying the mask is called a mask table, whilst the component carrying the wafer is called a wafer table. The mask table and the wafer table function as core components in respective mask stage subsystem and workpiece stage subsystem of the photolithography tool. Throughout the relative movements of the mask and wafer tables, both of the mask and wafer must be reliably fixed, i.e., constrained in all their six degrees of freedom, with respect to the respective tables.

Existing wafer tables utilize a so-called chuck to adsorb and hold a wafer. The chuck is adsorbed and thereby retained on a top surface of a square mirror, a core component of the wafer table, such that the wafer can move with the wafer table to a desired location along a predetermined path at a given speed. Since the surface of the wafer is coated with photoresist, most chucks are based on a suction approach. In order to enable position adjustments of the wafer table and to meet the requirements for leveling and focusing of the wafer, the square mirror is driven by a series of drives so as to be able to move in multiple degrees of freedom. Focal depth and overlay accuracy of the photolithography tool depend greatly on the accuracy of the chuck, which is measured by the profile accuracy of the upper and lower chuck surfaces and deformation upon the chuck being held.

The development of through silicon via (TSV), wafer thinning and wafer bonding technologies has in turn led to the presence of random wafer warps which can form gaps between warped wafer and chuck surface and thus disable the chuck to achieve a vacuum reaching a threshold for a satisfactory absorption effect. On the other hand, lowering the vacuum threshold may cause a decrease in retention robustness. All of these make an existing vacuum chuck unable to hold a warped wafer in a satisfying way.

Most of the existing wafer tables employ such vacuum chucks which fixedly retain a wafer by means of a vacuum suction force, i.e., retaining the wafer on the chuck top surface in a vacuum suction manner. While there have been proposed several chucks with special top surface profiles for minimizing the impacts, for example, deformation and thermal stress, occurring during the vacuum suction, none of them can address the issues associated with the suction retention of a warped wafer.

### SUMMARY OF THE INVENTION

It is therefore an objective of the present invention to address the issue of unsatisfactory retention of a warped wafer arising from the use of the conventional chucks by presenting an apparatus and method for retaining a warped wafer by suction.

In pursuit of this objective, the present invention provides an apparatus for adsorbing a wafer, which includes a chuck for vacuum adsorption of the wafer and at least three suction head assemblies, the chuck defining at least three openings each corresponding to one of the at least three suction head assemblies, wherein each of the at least three suction head assemblies includes: a pneumatic cylinder in fixed connection with the chuck; and a nozzle in movable connection to the pneumatic cylinder and movable under an actuation of the pneumatic cylinder between: a first position at which the nozzle is completely located within a corresponding one of the at least three openings; and a second position at which the nozzle is at least partially located above an upper surface of the chuck.

Preferably, the pneumatic cylinder includes a cylinder body, a piston and a guide column, the cylinder body is disposed under a corresponding one of the at least three openings and fixed to a bottom of the chuck, the guide column is disposed within the cylinder body and has a first end fixed to a bottom of the cylinder body and a second end inserted in the piston, and the piston has a lower portion located within the cylinder body and an upper portion in movable connection with the nozzle.

Preferably, the piston has an upper portion in movable connection with the nozzle by a ball head.

Preferably, the pneumatic cylinder further includes a spring disposed over a portion of the guide column between a bottom of the piston and the bottom of the cylinder body.

Preferably, the piston divides the pneumatic cylinder into a hermetic first pneumatic chamber and a hermetic second pneumatic chamber, the first pneumatic chamber is connected to a positive pressure source and the second pneumatic chamber is connected to a negative pressure source.

Preferably, the guide column defines a through bore and the nozzle defines a lumen connected to the second pneumatic chamber via the through bore of the guide column.

Preferably, the cylinder body is fixed to the bottom of the chuck by a screw.

Preferably, each of the at least three suction head assemblies further includes a position sensor arranged in the pneumatic cylinder, the position sensor is configured to initiate the vacuum adsorption of the chuck upon detecting that an upper surface of the nozzle is flush with an upper surface of the chuck.

Preferably, a vacuum sensor is arranged on the upper surface of the chuck, the vacuum sensor is configured to detect whether the wafer is adsorbed on the chuck.

Preferably, the at least three suction head assemblies are distributed on a circle centered at a center of the chuck.

Preferably, each of the at least three suction head assemblies is spaced from the center of the chuck by a distance having a ratio to a diameter of the chuck of 1:3 to 2:5.

Preferably, each nozzle has a diameter ranging from 5 mm to 100 mm.

The present invention also provides a method for adsorbing a wafer by using the apparatus as defined above and includes the steps of:
1) driving the nozzles to the respective first positions by the respective pneumatic cylinders, loading the wafer on the chuck, and initiating vacuum adsorption of the chuck for the wafer;
2) detecting whether the wafer is adsorbed on the chuck, and if the wafer has been adsorbed on the chuck, then completing the process, otherwise proceeding to step 3);
3) driving the nozzles to the respective second positions by the respective pneumatic cylinders such that upper surfaces of the nozzles comes into contact with the wafer and initiating vacuum suction of the nozzles to pull the wafer onto an upper surface of the chuck;
4) initiating vacuum adsorption of the chuck; and
5) ceasing the vacuum suction of the nozzles and driving the nozzles back to the respective first positions by the respective pneumatic cylinders.

Compared to the conventional apparatuses, the above described apparatuses according to the present invention each additionally include at least three suction head assemblies disposed in the chuck. The assemblies could, in the event of a warped wafer failing to be adsorbed on the chuck by suction, utilize their nozzles and pneumatic cylinders to bond to and thereby stretch the warped wafer until a bottom surface of the wafer adheres to a top surface of the chuck, thus achieving the adsorption of the warped wafer.

### BRIEF DESCRIPTION OF THE DRAWINGS

FIG. 1 is a schematic illustration of an apparatus for adsorbing a warped wafer by suction in accordance with an embodiment of the present invention.

FIG. 2 is a side view (partial cutaway view) of FIG. 1.

FIG. 3 is an enlarged view of the section I of FIG. 2.

FIGS. 4 to 6 are schematics illustrating a process of adsorbing a warped wafer by suction in accordance with an embodiment of the present invention.

FIG. 7 is a schematic illustration of a vacuum sensor.

FIG. 8 is a flowchart graphically illustrating a working process of an apparatus for adsorbing a warped wafer by suction in accordance with an embodiment of the present invention.

In these figures, 100—chuck, 101—opening, 200—suction head assembly, 210—nozzle, 220—ball head, 230—pneumatic cylinder, 231—cylinder body, 232—piston, 233—guide column, 234—spring, 235—first pneumatic chamber, 236—second pneumatic chamber, 237—screw, 240—position sensor, 300—warped wafer, and 401—vacuum sensor.

### DETAILED DESCRIPTION

The forgoing objectives, features and advantages of the present invention will become apparent from the following detailed description of illustrative embodiments thereof, which is to be read in connection with the accompanying drawings. Note that the accompanying drawings are provided in a very simplified form not necessarily presented to scale, with the only intention of facilitating convenience and clarity in explanation.

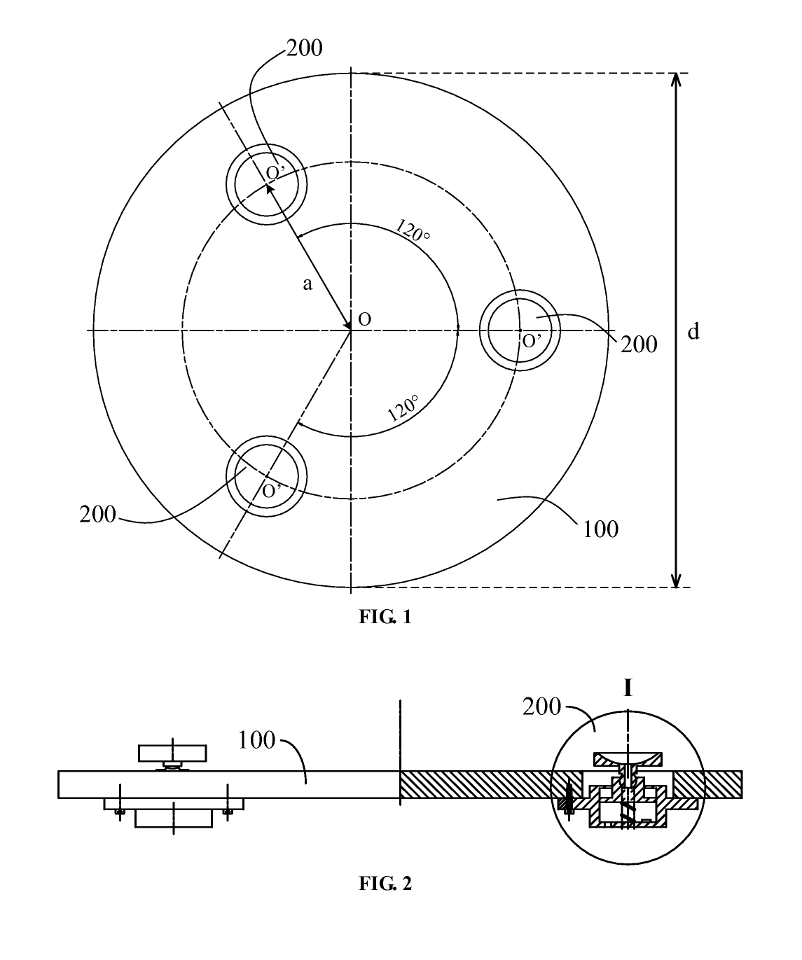

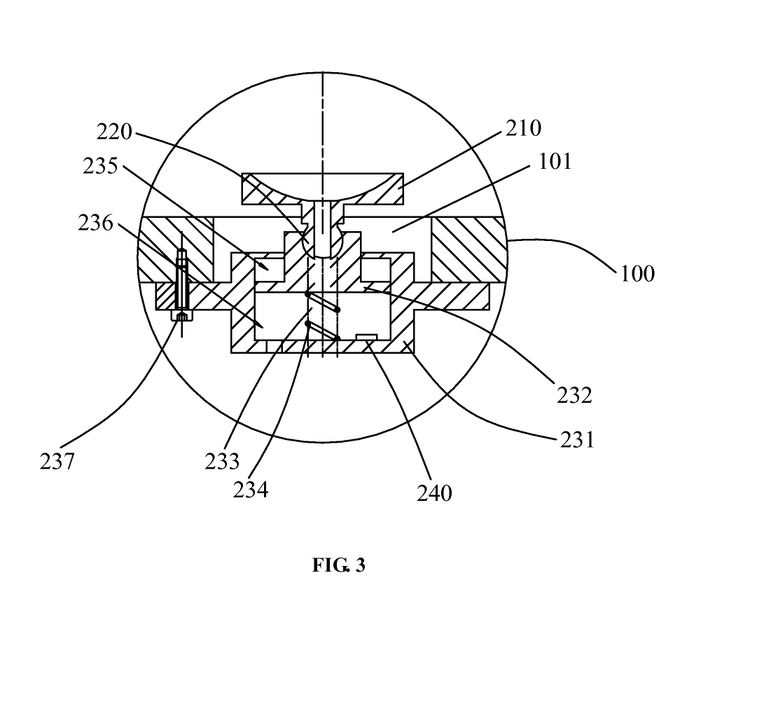

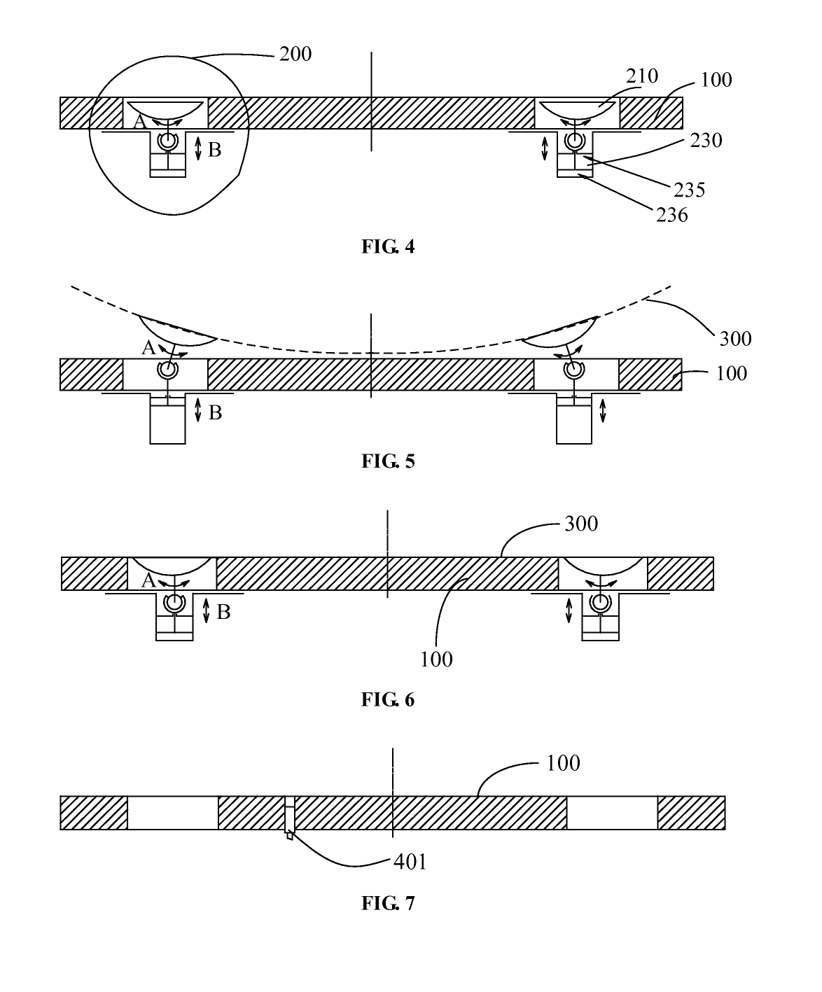

With reference to FIG. 1, additionally to FIGS. 2 to 6, an apparatus for adsorbing a warped wafer according to the present invention includes a chuck 100 and at least three suction head assemblies 200. The chuck defines at least three openings 101 with each of the three openings 101 corresponding to one of the suction head assemblies 200. Preferably, the suction head assemblies 200 are all distributed on a circle centered at a center O of the chuck 100. Specifically, each of the suction head assemblies 200 has a center O′ spaced from the center O of the chuck 100 by a distance of a which has a ratio to a diameter d of the chuck 100 of 1:3 to 2:5. The chuck 100 may be structurally similar to a conventional chuck, while the suction head assemblies 200, as shown in FIGS. 3 to 4, each include a nozzle 210, a ball head 220, a pneumatic cylinder 230 and a position sensor 240. The nozzle 210 may be completely received within a corresponding one of the openings 101 of the chuck 100 and have a diameter ranging from 5 mm to 100 mm. The nozzle 210 may be in movable connection (as indicated by the arrow A in FIGS. 4 to 6) to the pneumatic cylinder 230 via the ball head 220 and driven by the pneumatic cylinder 230 to move vertically with respect to a surface of the chuck 100 (as indicated by the arrow B in FIGS. 4 to 6). Specifically, under the actuation of the respective pneumatic cylinders 230, all the nozzles 210 may be located within the corresponding openings 101 or at least partially above the surface of the chuck 100. The position sensor 240 may be arranged within the pneumatic cylinder 230. According to this invention, with the at least three suction head assemblies 200, when a warped wafer 300 cannot be sealed with the chuck 100 due to vacuum leakage occurring therebetween and thus cannot be adsorbed on the chuck 100, the nozzles 210 of the suction head assemblies 200 each form a vacuum over a nearly planar area of the warped wafer 300. After the warped wafer 300 is adsorbed on the nozzles 210, the pneumatic cylinders 230 drive the respective nozzles 210 to move downward until the warped wafer 300 is pulled onto an upper surface of the chuck 100, thereby reducing gaps between the warped wafer 300 and the chuck 100. When the position sensors 240 detect that upper surfaces of the respective nozzles 210 are flush with the upper surface of the chuck 100, each of the position sensors 240 emits a signal to initiate vacuum adsorption of the chuck 100, thereby adsorbing the warped wafer 300 on the chuck 100.

Preferably, with emphasized reference to FIG. 3, the pneumatic cylinder 230 includes a cylinder body 231, a piston 232, a guide column 233 and a spring 234. Additionally, the guide column 233 is fixed within the cylinder body 231. Moreover, the piston 232 is disposed within the cylinder body 231 and has one end protruding out of the cylinder body 231 and movably connected to the nozzle 210 via the ball head 220. Further, the guide column 233 is inserted through the piston 232, and the spring 234 is disposed over a portion of the guide column 233 between the bottom of the piston 232 and the bottom of the cylinder body 231. Preferably, the piston 232 divides the pneumatic cylinder 231 into a hermetic first pneumatic chamber 235 and a hermetic second pneumatic chamber 236. In addition, the first pneumatic chamber 235 is connected to a positive pressure source, and the second pneumatic chamber 236 is connected to a negative pressure source. Specifically, the nozzle 210 may define a lumen that is connected with the second pneumatic chamber 236 via a through bore defined in the guide column 233. As a result, when the positive pressure source that is connected with the first pneumatic chamber 235 is turned on, the pressure in the first pneumatic chamber 235 increases and thus positions the nozzle 210 beneath the upper surface of the chuck 100. When the negative pressure source that is connected with the second pneumatic chamber 236 is turned on, the nozzle 210 generates a suction force to the warped wafer 300, as the second pneumatic chamber 236 is connected with the lumen of the nozzle 210. After a vacuum is formed, the pressure in the second pneumatic chamber 236 continues decreasing and thus causes the piston 232 and the nozzle 210 to move downward until the warped wafer 300 comes into close contact with the upper surface of the chuck 100.

Preferably, with continuing reference to FIG. 3, the cylinder body 231 is connected to the chuck 100 by a screw 237, in order to facilitate component detachment and replacement.

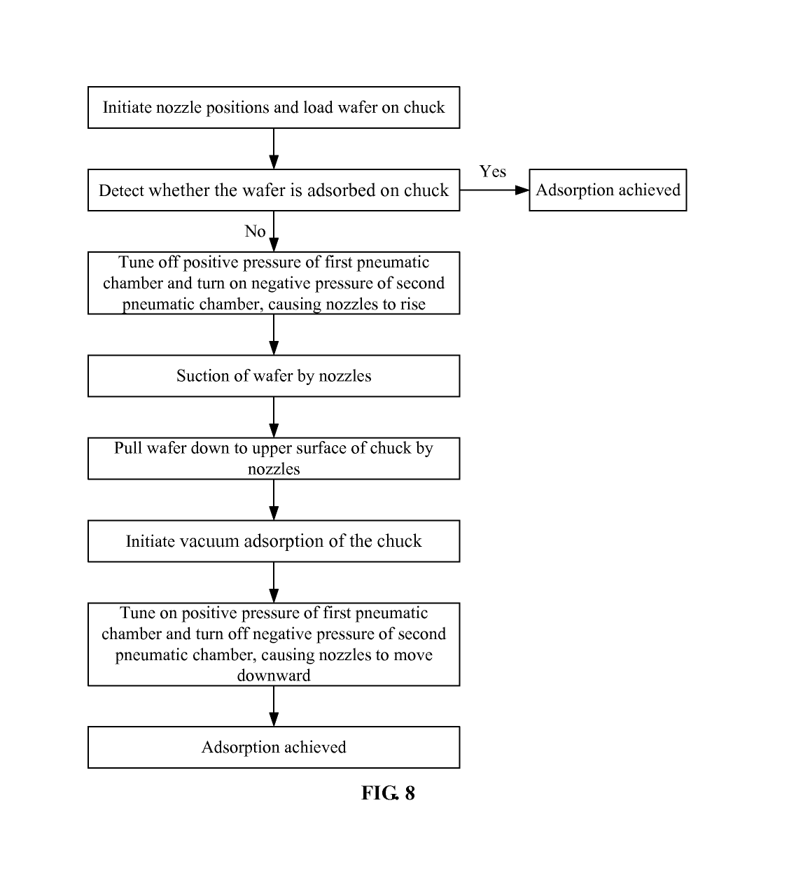

Preferably, a vacuum sensor 401 (FIG. 7) is further arranged on the upper surface of the chuck 100 and configured to detect whether the warped wafer 300 has been successfully adsorbed on the chuck 100. Upon the warped wafer 300 having been pulled by the nozzle 210 into close contact with the upper surface of the chuck 100, the chuck 100 starts to vacuum-adsorb the warped wafer 300. The vacuum sensor 401 then detects the vacuum adsorption of the warped wafer 300 on chuck 100 and transfers this information to the suction head assemblies 200, thus the suction head assemblies 200 responsively return to their respective initial positions. That is, the nozzles 210 release the warped wafer 300 and move downward to positions lower than the upper surface of the chuck 100 after the positive pressure source connected with the first pneumatic chamber 235 is turned on and the negative pressure source connected with the second pneumatic chamber 236 is turned off.

With reference to FIG. 8, additionally to FIGS. 4 to 7, a method for adsorbing a wafer according to the present invention uses an apparatus as defined above and includes the steps described below.

In a first step, each pneumatic cylinder 230 drives the respective nozzle 210 to move downward beneath the upper surface of the chuck 100 (at a position shown in FIG. 4). The wafer is then loaded and the chuck 100 starts to vacuum-adsorb the wafer.

In a second step, the vacuum sensor 401 detects whether the wafer is absorbed on the chuck 100. If the wafer is detected as having been absorbed on the chuck, the adsorption is accomplished. Otherwise, the process proceeds to the next step.

In a third step, the positive pressure source that is connected with the first pneumatic chamber 235 is turned on, causing the nozzle 210 to move upward. Specifically, the nozzle 210 may rise to a level that is determined by the warpage of commonly used wafers. In this embodiment, the nozzle 210 rises to a position 0.2 mm to 5 mm higher than the upper surface of the chuck 100. After the pneumatic cylinder 230 drives the nozzle 210 to rise to reach the warped wafer 300, the nozzle 210 comes into contact with the warped wafer 300, and the nozzle 210 pivots about the ball head 220 under the action of the weight of the warped wafer 300 to an orientation compatible with the warpage of the warped wafer 300. In this state (FIG. 5), the nozzle 210 fits on the warped wafer 300 and forms a seal therewith. After the negative pressure source that is connected with the second pneumatic chamber 236 is turned on, the nozzle 210 is bonded onto the warped wafer 300 by a suction force and then pulls the warped wafer 300 onto the upper surface of the chuck 100 (i.e., the state shown in FIG. 6).

In a fourth step, upon detecting that an upper surface of the nozzle 210 is flush with the upper surface of the chuck 100, the position sensor 240 emits a signal to initiate vacuum adsorption of the chuck 100, thereby causing the chuck 100 to adsorb on the warped wafer 300.

In a fifth step, upon detecting that the warped wafer 300 has been successfully adsorbed on the chuck 100, the vacuum sensor 401 outputs a signal to the suction head assemblies 200 to cause their nozzles 210 to stop the vacuum suction. The pneumatic cylinders 230 then drive the respective nozzles 210 to return to their initial positions. Specifically, the negative pressure sources that are connected with the respective second pneumatic chambers 236 are turned off, thereby releasing the nozzles 210 from the warped wafer 300. Next, the positive pressure sources that are connected with the respective first pneumatic chambers 235 are turned on to cause the respective nozzles 210 to move to positions beneath the upper surface of the chuck 100.

Preferably, the nozzles 210 move upward or downward under the control of the pneumatic cylinders 230 enabled by opening or closing the respective first pneumatic chambers 235 and second pneumatic chambers 236, during which the spring 234 acts as a buffer for protecting the wafer.

In summary, the apparatuses according to the present invention each additionally include in the chuck 100 at least three suction head assemblies 200, when a warped wafer 300 fails to be adsorbed on the chuck 100, the suction head assemblies 200 can utilize their nozzles 210 and pneumatic cylinders 230 to adsorb and thereby stretch the warped wafer 300 until a bottom surface of the warped wafer 300 adheres to a top surface of the chuck 100, thus achieving the adsorption of the warped wafer 300.

It is apparent that those skilled in the art can make various changes and modifications without departing from the spirit and scope of the present invention. Therefore, it is intended that all such changes and modifications fall within the scope of the invention as defined by the appended claims and their equivalents.

What is claimed is:

1. An apparatus for adsorbing a wafer, comprising a chuck for vacuum adsorption of the wafer and at least three suction head assemblies, the chuck defining at least three openings each corresponding to one of the at least three suction head assemblies,
wherein each of the at least three suction head assemblies includes:
a pneumatic cylinder in fixed connection with the chuck; and
a nozzle in movable connection to the pneumatic cylinder and movable under an actuation of the pneumatic cylinder between:
a first position at which the nozzle is completely located within a corresponding one of the at least three openings; and
a second position at which the nozzle is at least partially located above an upper surface of the chuck.

2. The apparatus of claim 1, wherein the pneumatic cylinder includes a cylinder body, a piston and a guide column, the cylinder body disposed under a corresponding one of the at least three openings and fixed to a bottom of the chuck, the guide column disposed within the cylinder body and having a first end fixed to a bottom of the cylinder body and a second end inserted in the piston, the piston having a lower portion within the cylinder body and an upper portion in movable connection with the nozzle.

3. The apparatus of claim 2, wherein the piston has an upper portion in movable connection with the nozzle by a ball head.

4. The apparatus of claim 2, wherein the pneumatic cylinder further includes a spring disposed over a portion of the guide column between a bottom of the piston and the bottom of the cylinder body.

5. The apparatus of claim 2, wherein the piston divides the pneumatic cylinder into a hermetic first pneumatic chamber and a hermetic second pneumatic chamber, the first pneumatic chamber connected to a positive pressure source, the second pneumatic chamber connected to a negative pressure source.

6. The apparatus of claim 5, wherein the guide column defines a through bore and the nozzle defines a lumen connected to the second pneumatic chamber via the through bore of the guide column.

7. The apparatus of claim 2, wherein the cylinder body is fixed to the bottom of the chuck by a screw.

8. The apparatus of claim 1, wherein each of the at least three suction head assemblies further includes a position sensor arranged in the pneumatic cylinder, the position sensor configured to initiate the vacuum adsorption of the chuck upon detecting that an upper surface of the nozzle is flush with an upper surface of the chuck.

9. The apparatus of claim 1, wherein a vacuum sensor is arranged on the upper surface of the chuck, the vacuum sensor configured to detect whether the wafer is adsorbed on the chuck.

10. The apparatus of claim 1, wherein the at least three suction head assemblies are distributed on a circle centered at a center of the chuck.

11. The apparatus of claim 10, wherein each of the at least three suction head assemblies is spaced from the center of the chuck by a distance having a ratio to a diameter of the chuck of 1:3 to 2:5.

12. The apparatus of claim 1, wherein each nozzle has a diameter ranging from 5 mm to 100 mm.

13. A method for adsorbing a wafer by using the apparatus as defined in claim 1, the method including the steps of:
1) driving the nozzles to the respective first positions by the respective pneumatic cylinders, loading the wafer on the chuck, and initiating vacuum adsorption of the chuck for the wafer;
2) detecting whether the wafer is adsorbed on the chuck, and if the wafer has been adsorbed on the chuck, then completing the method, otherwise proceeding to step 3);
3) driving the nozzles to the respective second positions by the respective pneumatic cylinders such that upper surfaces of the nozzles come into contact with the wafer and initiating vacuum suction of the nozzles to pull the wafer onto an upper surface of the chuck;
4) initiating vacuum adsorption of the chuck; and
5) ceasing the vacuum suction of the nozzles and driving the nozzles back to the respective first positions by the respective pneumatic cylinders.
